(19) United States
(12) Patent Application Publication
(10) Pub. No.: US 2025/0317692 A1
(43) Pub. Date: Oct. 9, 2025

(54) MICROELECTROMECHANICAL DEVICE FOR INTERACTION WITH A FLUID PRESSURE

(71) Applicant: Robert Bosch GmbH, Stuttgart (DE)

(72) Inventors: Anton Melnikov, Dresden (DE); Alexander Sorger, Dresden (DE); Jens Schindele, Kirchentellinsfurt (DE); Maximilian Sommer, Dresden (DE)

(21) Appl. No.: 19/171,523

(22) Filed: Apr. 7, 2025

(30) Foreign Application Priority Data
Apr. 9, 2024 (DE) 10 2024 203 210.7

(51) Int. Cl. H04R 17/00; H04R 7/18; H04R 31/00

(52) U.S. Cl. CPC H04R 17/00; H04R 7/18; H04R 31/006; H04R 2201/003

(57) ABSTRACT

A microelectromechanical device for interaction with a fluid pressure. The microelectromechanical device includes a displacer structure, wherein the displacer structure comprises a movable lamella, wherein the lamella has a width, a length, and a thickness, wherein the lamella is movable, wherein the lamella has at least one edge region, wherein the lamella comprises a cross piece in the edge region, which cross piece laterally projects at least beyond one side surface of the lamella, wherein a stopper element is arranged on an edge region of the cross piece, which stopper element projects beyond the cross piece in a specified direction, wherein, when the lamella is moved in the specified direction, the stopper element comes to rest on a boundary surface first, before the cross piece.

### FIELD

The present invention relates to a microelectromechanical device for interaction with a fluid pressure with stopper elements for avoiding damage to the displacer structure when it comes rest on a further element.

### BACKGROUND INFORMATION

U.S. Patent Application Publication No. US 2021/297787 describes a MEMS speaker which usually has planar structures, wherein a vibratable membrane is excited such that the fluid is displaced and/or compressed vertically to the membrane plane. Such membranes are typically excited by means of a piezoelectric or electrostatic effect.

### SUMMARY

An object of the present invention is to provide a microelectromechanical device for interaction with a fluid pressure, wherein the reliability of the function of a displacer structure is improved.

The object of the present invention may be achieved by certain features of the present invention.

According to an example embodiment of the present invention, a microelectromechanical device for interaction with a fluid pressure is provided. This device has a displacer structure. The displacer structure has a movable lamella, wherein the lamella has a width, a length, and a thickness. The lamella is movable, wherein the lamella comprises a cross piece (web) at least in one edge region, which cross piece projects laterally at least over a side surface of the lamella. Depending on the chosen embodiment, the cross piece can project beyond both side surfaces of the lamella. A stopper element is arranged on an edge region of the cross piece and projects in a specified direction, in particular perpendicularly to the side surface of the lamella, beyond the cross piece.

The displacer structure can be arranged adjacent to a chamber, i.e., a cavity, or in a chamber. The displacer structure can be fastened to a second element of the device, in particular to a carrier or a wall of the device. In preferred embodiment examples, the carrier is a substrate. Particularly preferably a semiconductor substrate.

When the lamella is moved actively or passively in a specified direction, the stopper element is first brought to rest on a boundary surface. The boundary surface can be any surface of the device, in particular a surface of a wall, of a cavity, of a further lamella, of a cross piece of a further lamella, and/or of a further stopper element.

This prevents the cross piece from resting on a boundary surface in an undefined manner. In addition, the stopper element can reduce or prevent adhesion, adherence, or sticking of the cross piece to the boundary surface. In addition, the cross piece is protected against a collision with a boundary surface since the stopper element impacts the boundary surface when the lamella is deflected accordingly.

The stopper element can thus absorb kinetic energy and protect the cross piece from becoming fixed. In addition, the stopper element can in particular be formed from an elastic material that dampens impact of the stopper element on the boundary surface. Thus, the cross piece is in particular protected from damage by the lamella impacting the boundary surface.

In one example embodiment of the present invention, the cross piece is designed to project on two opposing side surfaces of the lamella. In particular, the edge region is designed in a T shape in a cross-section perpendicular to a side surface of the lamella.

Depending on the chosen embodiment of the present invention, the cross piece can extend at least over a specified length of the edge region, in particular over at least 50% of a total length of the edge region of the lamella, or preferably over the entire length of the edge region of the lamella.

Depending on the chosen embodiment of the present invention, the lamella comprises multiple cross pieces on multiple edge regions. In addition, multiple cross pieces can also comprise at least one stopper element, which protects the cross piece from impacting a boundary surface.

Depending on the chosen embodiment of the present invention, a second lamina can be provided, wherein the second lamina is arranged in a possible deflection region of the lamina and is a boundary surface, wherein, when the lamina is deflected, the stopper element of the lamina comes to rest on the second lamina. This protects the cross piece of the lamella against resting on or impacting the second lamella.

In a further embodiment of the present invention, the second lamella also comprises a stopper element, wherein the stopper element is a boundary surface. In addition, the second lamella can also comprise a cross piece, wherein the cross piece projects laterally at least beyond a side surface of the second lamella. In addition, a stopper element that projects beyond the cross piece of the second lamina in a specified direction can be arranged on an edge region of the cross piece. When the second lamella is moved in the specified direction, the stopper element of the second lamella is first moved to rest on a boundary surface represented by the lamella. In this way, the second lamella is also protected from undefined impact of the cross piece on a boundary surface.

Depending on the chosen embodiment of the present invention, the stopper element can be resilient and/or can be mounted resiliently on the cross piece. For example, the stopper element itself may be formed from an elastic material for this purpose. Furthermore, the stopper element can be fastened to the cross piece via a spring element. In this way, the force transmission is dampened when the stopper element impacts a boundary surface. Influences on the movement or damages due to the stopper element impacting the boundary surface too hard can thus be reduced or avoided. After a specified spring travel, the spring element can impact the lamella or the cross piece of the lamella. A two-stage braking process is thus made possible.

Depending on the chosen embodiment of the present invention, the lamella can comprise multiple stopper elements on the at least one cross piece. This can increase the certainty that one of the stopper elements rather than the cross piece itself impacts a boundary surface. In addition, in the case of an elastic design of the stopper elements, for example, an impact force can be better dampened by the multiple stopper elements.

Depending on the chosen embodiment of the present invention, the lamella can be fastened with one edge region to a carrier, wherein the lamella comprises at least one cross piece with a stopper element on the further free edge regions. In particular, the lamella can comprise two or three cross pieces along the two or three free edge regions.

Depending on the chosen embodiment of the present invention, the boundary surface can be a wall of the chamber and/or a surface of a further lamella, in particular a cross piece of a further lamella.

The present invention is explained with reference to the figures.

### BRIEF DESCRIPTION OF THE DRAWINGS

FIG. 1A to 1H show various embodiments of Mems components with displacer structures with lamellae and cross pieces, according to the present invention.

FIG. 2A to 2F show various arrangements of displacer structures in Mems components, according to example embodiments of the present invention.

FIG. 3A to 3D show further embodiments of displacer structures in Mems components, according to the present invention.

FIG. 4A to 4C show a further embodiment of a displacer structure in various positions, according to the present invention.

### DETAILED DESCRIPTION OF EXAMPLE EMBODIMENTS

Microelectromechanical devices, i.e., MEMS components, can be multilayered layer structures. Such MEMS components can be obtained, for example, by processing semiconductor material at the wafer level, which can also include a combination of multiple wafers and/or the deposition of layers onto wafer planes. Embodiment examples described here can relate to layer stacks with multiple layers. However, layers described in this context may, but do not necessarily have to, be a single layer, but, in embodiment examples, they may easily comprise two, three, or more layers and be understood as a layer composite. Thus, both layers from the material of which a movable element is formed and layers between which a movable element is arranged can be formed with multiple layers, which can be designed, for example, as at least a part of a wafer and can comprise multiple layers of material, for example for implementing physical, chemical, and/or electrical functions. Some of the embodiment examples described here are described in connection with a loudspeaker configuration or a loudspeaker function of a corresponding MEMS component. It is understood that these statements, with the exception of the alternative or additional function of a sensor-based evaluation of the MEMS component or of the movement or position of movable elements thereof, can be transferred to a microphone configuration or microphone function of the MEMS component so that such microphones represent, without restriction, further embodiment examples of the present invention. Furthermore, other applications of MEMS are also within the scope of embodiment examples described here, such as micropumps, ultrasonic transducers, or other MEMS-based applications that are related to moving fluid. For example, embodiment examples can relate to a movement of actuators that can interact with a fluid, among other things. Embodiment examples relate to an application of electrostatic forces for deflecting a movable element. However, the described embodiment examples can easily be implemented using other drive principles, such as electromagnetic force generation or sensing. The deflectable elements may, for example, be electrostatic, piezoelectric, and/or thermomechanical electrodes that provide deformation based on an applied potential. Corresponding drives are described in PCT Patent Application No. WO 002022117197 A1, for example.

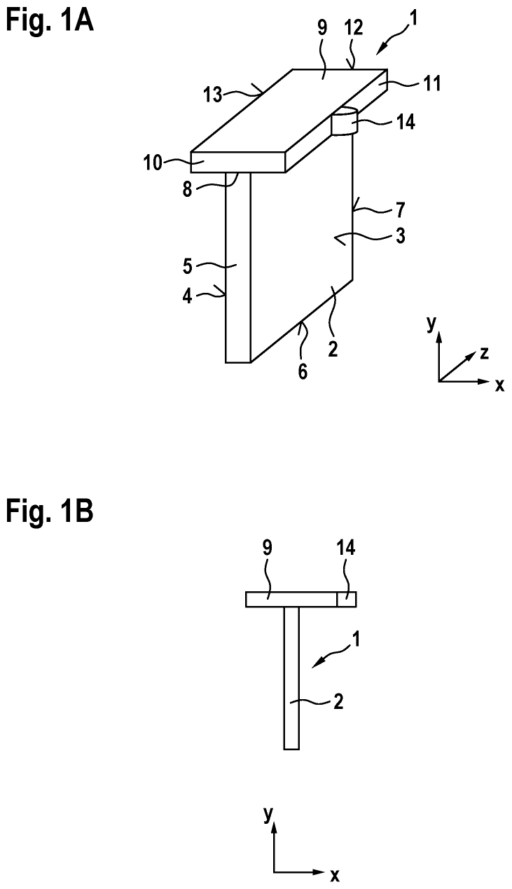

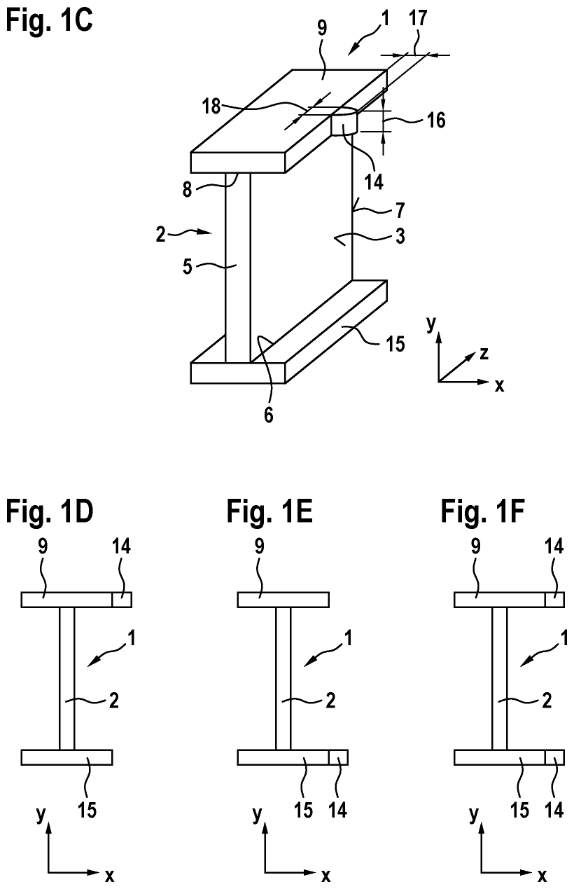

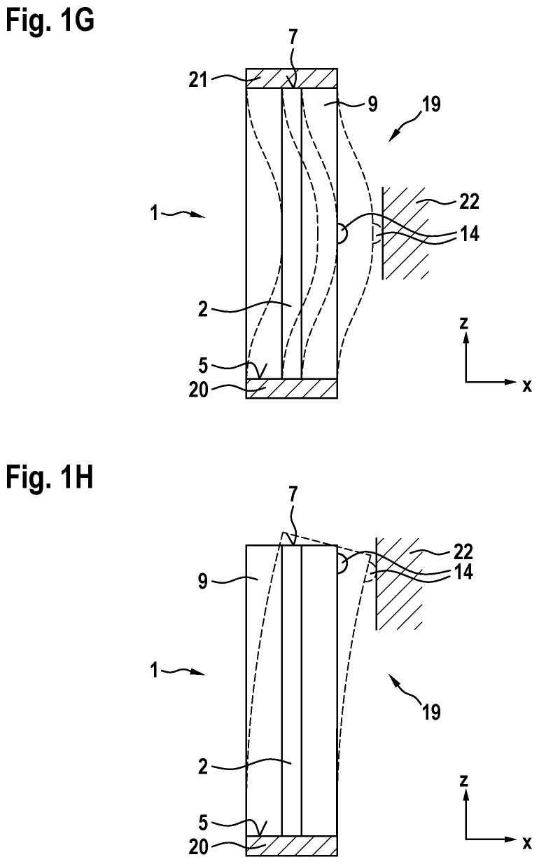

FIG. 1A shows a schematic perspective partial illustration of a portion of a Mems component with a displacer structure 1 comprising a lamella 2. The lamella 2 has a specified length along the Y direction, a specified width along the Z direction, and a specified thickness along the X direction. In the illustrated embodiment, the lamella 2 is plate-shaped, wherein a first side surface 3 is aligned in the X direction and a second side surface 4 is aligned opposite the X direction. The lamella 2 has four edge regions 5, 6, 7, 8. A cross piece 9 is formed on the fourth edge region 8. In the illustrated embodiment, the cross piece 9 extends over the entire length of the fourth edge region 8. In addition, the cross piece 9 projects beyond both the first side surface 3 and the second side surface 4 along the X direction. Depending on the chosen embodiment, the cross piece 9 can also extend only beyond one side surface of the lamella 2 along the X direction. The cross piece 9 is plate-shaped and has four further edge regions 10, 11, 12, 13.

In the illustrated embodiment example, the cross piece 9 comprises a stopper element 14 on the second further edge region 11. In the illustrated embodiment, the stopper element 14 projects in the X direction beyond the second further edge region 11. Depending on the chosen embodiment, the cross piece 9 can also comprise one or more stopper elements 14 on each of the further edge regions. In the illustrated embodiment, the stopper element 14 is arranged approximately in the central region of the second further edge region 11 when viewed in the Z direction. Depending on the chosen embodiment, the stopper element 14 can also be arranged on an upper or lower end region when viewed along the Z direction.

FIG. 1B shows a schematic cross-section in the YX plane through the displacer structure 1 of FIG. 1A.

FIG. 1C shows a further embodiment of a displacer structure 1, which is substantially designed according to the embodiment of FIG. 1A, wherein, however, a second cross piece 15 is arranged on the second edge region 6 of the lamella 2. The second cross piece 15 in the illustrated embodiment is designed with the same dimensions and in the same arrangement as the cross piece 9, wherein, however, no stopper element 14 is provided. Depending on the chosen embodiment, at least one or more stopper elements 14 can also be arranged on the second cross piece 15 on one or more of the further edge regions of the second cross piece 15. In addition, the second cross piece 15 can also have different dimensions and/or a different arrangement on the lamella 2 than the cross piece 9.

In all embodiments, the stopper element 14 can have a height 16 in the range of 100 nm to 100 μm, preferably 500 nm to 10 μm, particularly preferably 700 nm to 5 μm, along the Y-axis. The length 17 of the stopper element along the X direction can be in the range of 100 nm to 100 μm, preferably 500 nm to 10 μm, particularly preferably 700 nm to 5 μm. A width 18 of the stopper element along the Z direction can be in the range of 100 nm to 300 μm, preferably 500 nm to 100 μm, particularly preferably 1 μm to 30 μm. The stopper element 14 can have various shapes, wherein a partially cylindrical, partially ellipsoid, rectangular, or trapezoidal configuration of the stopper element 14 is advantageous.

FIG. 1D shows a schematic cross-section in the YX plane through the displacer structure of FIG. 1C.

FIG. 1E shows a schematic cross-section through a further embodiment of a displacer structure 1, in which the stopper element 14 is arranged on the second cross piece 15.

FIG. 1F shows a further embodiment of a displacer structure 1, which is designed substantially according to the embodiment of FIG. 1C, wherein, however, in this embodiment, a stopper element 14 is arranged on both the cross piece 9 and the second cross piece 15. Depending on the chosen embodiment, stopper elements 14 can also be arranged on all edge regions of the cross pieces 9 and/or of the second cross piece 15.

FIG. 1G and 1H show the displacer structure 1 at rest with solid lines and in the deflected state with dashed lines.

FIG. 1G shows a schematic cross-sectional illustration of a displacer structure 1, which is arranged in a chamber, i.e., a cavity 19, in the example shown. In this embodiment, the lamella 2 of the displacer structure 1 is fastened with the first edge region 5 to a first element 20 of the device, for example a carrier, a substrate, or a wall of the device, and with the third edge region 7 to a second element 21, for example a carrier, a substrate, or a further wall of the device. In addition, a third element 22, in particular a further wall, is arranged laterally at a distance from the displacer structure 1 in the X direction. If the displacer structure 1 is deflected either actively or passively in the X direction toward the third element 22, the cross piece 9 is prevented from resting directly on the third element 22 since the stopper element 14 comes to rest thereon first. Depending on the chosen embodiment, the displacer structure 1 can have the shape of FIG. 1A or FIG. 1C so that a stopper element 14 of the second cross piece 15 can also come to rest on the third element 22.

FIG. 1H shows a further embodiment with a displacer structure 1, which is arranged in a chamber, i.e., a cavity 19, wherein the lamella 2 in this embodiment is fastened only with the first edge region 5 to the first element 20. The opposite end of the lamella 2, that is, the third edge 7, is freely movable in this embodiment. In addition, the stopper element 14 in this embodiment is also arranged on the cross piece 9 in the upper end region, that is, close to the height of the third edge region 7. If the displacer structure 1 is bent in the X direction with the free end toward the third element 22, only the stopper element 14 comes to rest on the third element 22.

FIG. 1H and 1G schematically show the deflected positions of the displacer structure 1 in the form of dashed outer contours of the displacer structure 1.

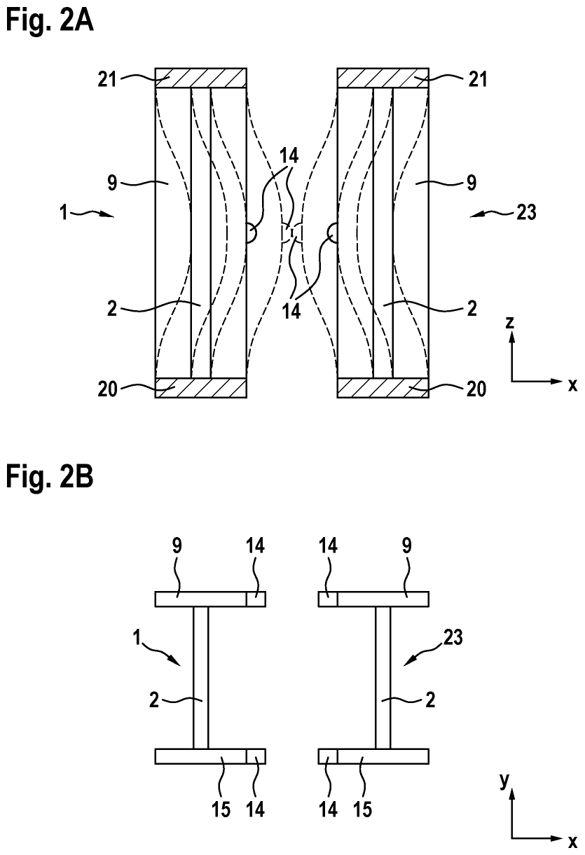

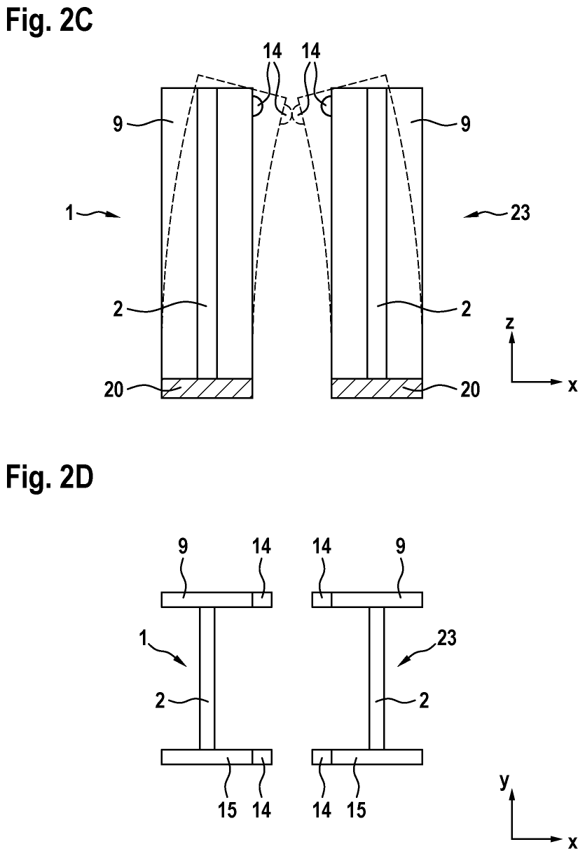

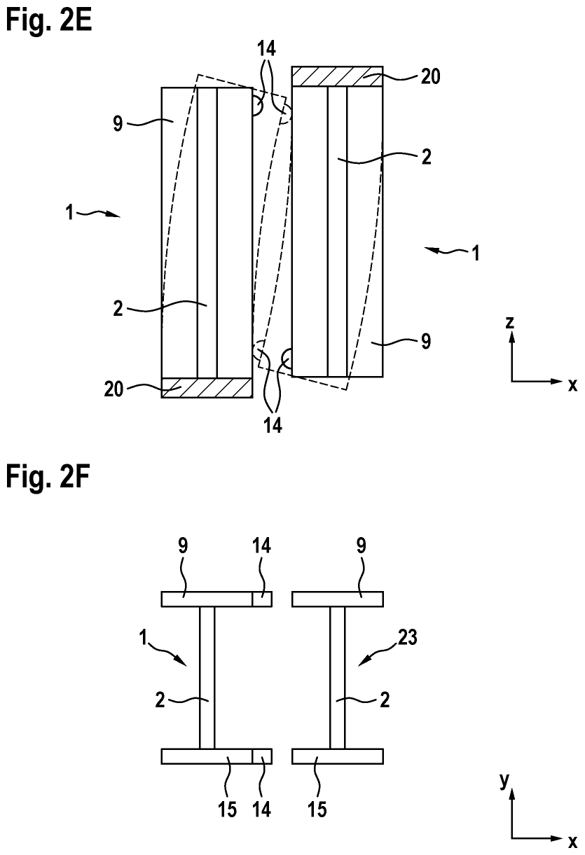

FIGS. 2A, 2C, and 2E show the displacer structures 1, 23 at rest with solid lines and in the deflected state with dashed lines.

FIG. 2A shows an arrangement of two side-by-side displacer structures 1, 23 arranged and designed substantially according to the embodiment of FIG. 1G, wherein the two displacer structures 1, 23 are arranged so close to each other in the X direction that, when they are simultaneously deflected toward each other, stopper elements 14 of the two displacer structures 1, 23 can be brought to rest on one another. In this case, the stopper elements 14 of the two displacer structures 1, 23 are each arranged in a center region of the corresponding cross pieces. Depending on the chosen embodiment, the lamellae of the displacer structures can have one or two cross pieces 9, 15 according to the embodiments of FIG. 1A or 1C.

FIG. 2B shows a schematic cross-section through the arrangement of FIG. 2A at the height of the stopper element 14. FIG. 2C is a schematic illustration of two displacer structures 1, 23, wherein each displacer structure is designed according to the displacer structure 1 of FIG. 1H. The two displacer structures 1, 23 are arranged so close to each other that, when the displacer structures 1, 23 are deflected toward each other, the stopper elements 14 of the two displacer structures 1, 23 can each be brought to rest on one another, as shown schematically in dashed lines in FIG. 2C.

FIG. 2D shows a corresponding cross-section through the arrangement of FIG. 2C.

FIG. 2E shows a further arrangement of two displacer structures 1, 23, wherein each displacer structure is designed analogously to the displacer structure 1 of FIG. 1H, wherein, however, the displacer structure 1 is fastened with the first edge region 5 to a first element 20, whereas the second displacer structure 23 is fastened with a third edge region 7 to a first element 20. In addition, when the two displacer structures 1, 23 are simultaneously deflected toward each other, stopper elements 14 can in each case be brought to rest on the cross piece of the other displacer structure. The deflected positions of the two displacer structures 1, 23 are in turn shown schematically as dashed outer contours.

FIG. 2F shows a schematic cross-section through the arrangement of FIG. 2E at the height of the stopper element 14 or the stopper elements 14 of the displacer structure 1.

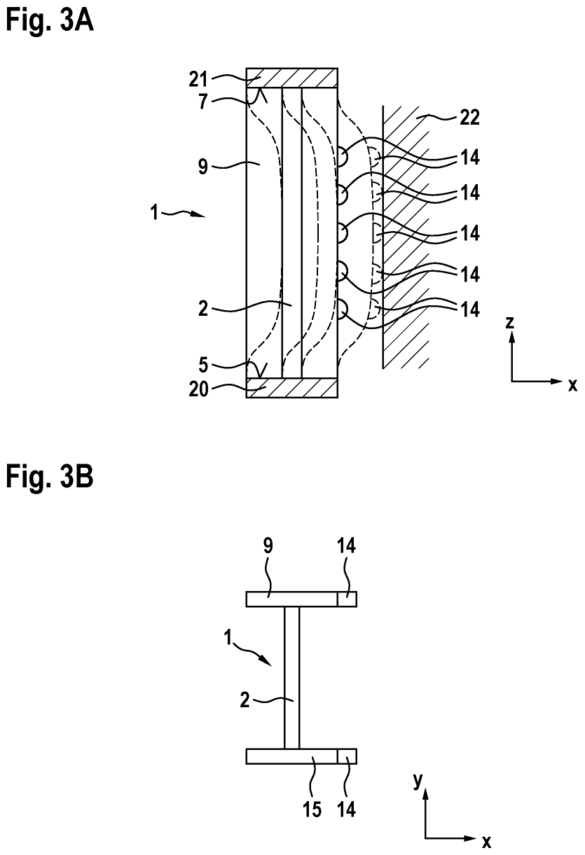

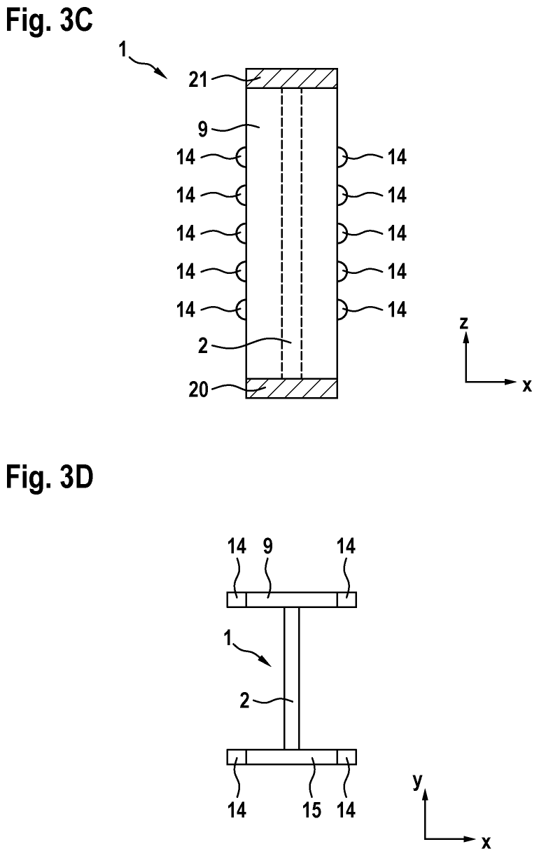

FIG. 3A shows the displacer structure 1 at rest with solid lines and in the deflected state with dashed lines.

FIG. 3A shows a schematic illustration of an arrangement according to FIG. 1G with a displacer structure 1 connected with a first edge region 5 to a first element 20 and with an opposite third edge region 7 to a second element 21. In addition, a third element 22 is arranged laterally at a distance in the X direction. In this embodiment, the lamella 2 of the displacer structure 1 can comprise at least one or two cross pieces 9, 15. In addition, at least one or both cross pieces can comprise stopper elements 14, which, when the lamella 2 is deflected toward the third element 22, come to rest on the third element 22, as shown schematically in the form of dashed lines.

By providing multiple stopper elements, more and more stopper elements 14 can come to rest on the third element 22 as the load increases, that is, as the lamella 2 is increasingly bent, so that a stepwise cushioning of the lamella 2 is achieved when coming to rest on the third element 22.

FIG. 3B shows a schematic cross-section through the arrangement of FIG. 3A. The stopper elements 14 are arranged in such a way that direct contact between one of the cross pieces 9, 15 and the third element 22 is avoided.

FIG. 3C shows a further embodiment, which is designed substantially according to the embodiment of FIG. 3A, wherein, however, the cross piece 9 and/or the second cross piece 15 in this embodiment comprises stopper elements 14 on both sides in order to prevent the cross piece 9 or the second cross piece 15 from coming to rest directly on a third element during a deflection in the X direction or in the direction opposite to the X direction. In this embodiment, on both sides, the stopper elements 14 thus also come to rest on a corresponding element first.

FIG. 3D shows a cross-section in the YX plane through the arrangement of FIG. 3C.

The arrangements of FIG. 3A to 3D can also be used when the displacer structure is fastened on only one side to an element.

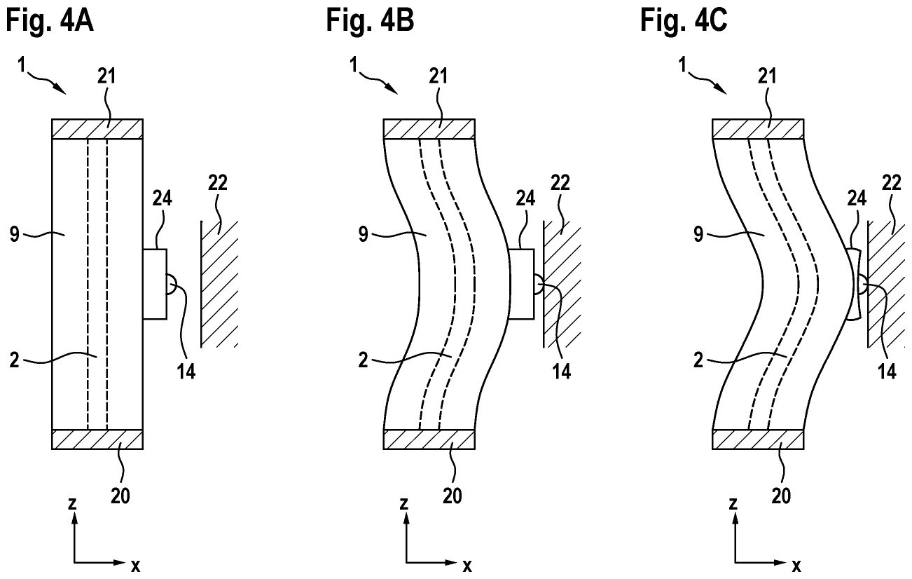

FIG. 4A shows a further embodiment of a displacer structure 1, in which the stopper element 14 is formed with an elastic effect on the cross piece 9 and/or on the second cross piece 15. For example, the stopper element 14 itself may be formed from an elastic material for this purpose. In addition, as shown schematically in the figure, a spring element 24 can be arranged between the cross piece 9 or the second cross piece 15 and the stopper element 14. For example, the spring element 24 can be formed materially uniformly with the cross piece 9 or the second cross piece 15. For example, the spring element 24 is a bendable cross piece that is fastened on one side or two sides to the cross piece 9 or to the second cross piece 15.

FIG. 4B shows the displacer structure 1 during a deflection in the X direction toward the third element 22. The stopper element 14 comes to rest on the third element 22 due to the corresponding protruding arrangement of the stopper element 14.

FIG. 4C shows the operating principle of the spring element 24, which consists in bending when the stopper element 14 comes to rest on the third element 22, and thus in reducing the contact forces between the stopper element 14 and the third element 22.

Upon further movement toward the second element 21, the spring element 24 can come to rest on the corresponding cross piece 9, 15. A two-stage braking process is thus made possible. Depending on the chosen embodiment, multiple spring stages can also be realized by the arrangement, for example multiple spring elements which are designed accordingly.

The first, second, and/or third element 20, 21, 22 can be part of a cavity and can in particular bound a cavity in which at least one displacer structure 1 is arranged.

The displacer structures described can be used in various microelectromechanical systems, in particular MEMS-based speakers, microphones, micropumps, pressure sensors, or other types of MEMS elements in which the displacer structures interact with fluids.

1-10. (canceled)

11. A microelectromechanical device for interaction with a fluid pressure, comprising:
a displacer structure including a movable lamella, wherein the lamella has a width, a length, and a thickness, wherein the lamella is movable, wherein the lamella has at least one edge region, wherein the lamella includes a cross piece in the edge region, the cross piece laterally projecting at least beyond one side surface of the lamella, wherein a stopper element is arranged on an edge region of the cross piece, the stopper element projecting beyond the cross piece in a specified direction, wherein, when the lamella is moved in a specified direction, the stopper element comes to rest on a boundary surface first, before the cross piece.

12. The device according to claim 11, wherein the cross piece projects on two opposing side surfaces of the lamella, wherein, the lamella with the cross piece has a T shape in a cross-section perpendicular to a side surface of the lamella.

13. The device according to claim 11, wherein the cross piece extends along at least 50% of an entire length of an edge region of the lamella.

14. The device according to claim 11, wherein the cross piece extends over an entire length of an edge region of the lamella.

15. The device according to claim 11, wherein the lamella has multiple edge regions, wherein a cross piece is formed on each of the edge regions, wherein a stopper element is arranged on each cross piece.

16. The device according to claim 11, wherein the device further comprises a second displacer structure with a further lamella, wherein the further lamella is arranged in a possible deflection region of the lamella of the displacer structure, and wherein, when the displacer structure is deflected, the stopper element of the lamella comes to rest on the further lamella of the second displacer structure.

17. The device according to claim 16, wherein the further lamella of the second displacer structure includes a cross piece at least in one edge region, wherein the cross piece of the further lamella projects laterally at least beyond a side surface of the second lamella, wherein a stopper element is arranged on an edge region of the cross piece of the further lamella and projects beyond the cross piece of the further lamella in a specified direction, wherein, when the second displacer structure is moved in the specified direction, the stopper element comes to rest first on a boundary surface of a wall and/or on the stopper element of the lamella.

18. The device according to claim 11, wherein the stopper element is mounted resiliently on the cross piece.

19. The device according to claim 11, wherein the lamella includes multiple stopper elements on the cross piece.

20. The device according to claim 11, wherein the displacer structure is fastened with an edge region of the lamella to a carrier, wherein the lamella includes at least one cross piece on further free edge regions.

21. The device according to claim 11, wherein the boundary surface is formed: (i) by a wall of a cavity and/or (ii) by a surface of a further lamella and/or (iii) by a surface of a cross piece of the further lamella.
